(19) United States
(12) Patent Application Publication
(10) Pub. No.: US 2014/0312190 A1
(43) Pub. Date: Oct. 23, 2014

(54) MOUNTING STRUCTURE FOR POWER SUPPLY

(71) Applicant: HON HAI PRECISION INDUSTRY CO., LTD., New Taipei (TW)

(72) Inventor: TE-MING CHANG, New Taipei (TW)

(73) Assignee: HON HAI PRECISION INDUSTRY CO., LTD., New Taipei (TW)

(21) Appl. No.: 13/890,260

(22) Filed: May 9, 2013

(30) Foreign Application Priority Data
Apr. 18, 2013 (TW) 102113743

(51) Int. Cl. H05K 7/14; F16M 13/02

(52) U.S. Cl. CPC H05K 7/14; F16M 13/02
USPC 248/311.2

(57) ABSTRACT

A mounting structure includes a casing for receiving a power supply, a connecting member, and a fastener. The casing includes an end wall defining a mounting hole and a positioning hole below the mounting hole. The connecting member includes a connecting plate defining a through hole, and a hook. The fastener extends through the through hole of the connecting member, to latch in the mounting hole of the casing. The hook of the connecting member is latched into the positioning hole of the casing.

### BACKGROUND

1. Technical Field

The disclosure relates to a mounting structure for a power supply.

2. Description of Related Art

In a container data center, a power supply is usually received in a casing, and the casing is mounted to a rack of the container data center by connecting members. The connecting members are mounted to the casing only using screws, thus the screws may loosen after being used for a long period of time. Therefore, the power supply may vibrate too much to be damaged.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a mounting structure, wherein the mounting structure includes a connecting member.

FIG. 2 is an enlarged, isometric view of the connecting member of FIG. 2, but viewed from another perspective

FIG. 3 is an assembled, isometric view of FIG. 1.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

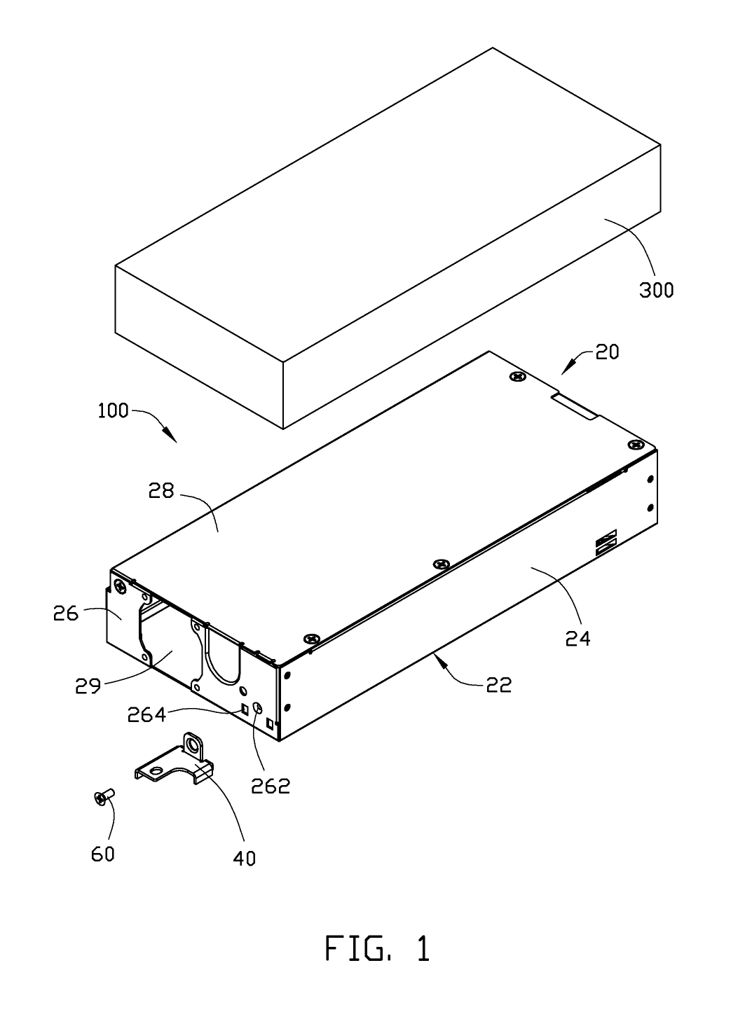

FIG. 1 shows an exemplary embodiment of a mounting structure 100. The mounting structure 100 includes a casing 20, a connecting member 40, and a fastener 60.

The casing 20 includes a rectangular bottom wall 22, two sidewalls 24 perpendicularly extending up from two opposite sides of the bottom wall 22, two end walls 26 perpendicularly extending up from two opposite ends of the bottom wall 22 and connected between corresponding ends of the sidewalls 24, and a top wall 28 opposite to the bottom wall 22 and connected among top sides of the sidewalls 24 and the end walls 26. The bottom wall 22, the sidewalls 24, the end walls 26, and the top wall 28 cooperatively bound a receiving space 29 for receiving a power supply 300. A bottom corner of one of the end walls 26 defines a mounting hole 262 and two positioning holes 264 below the mounting hole 262.

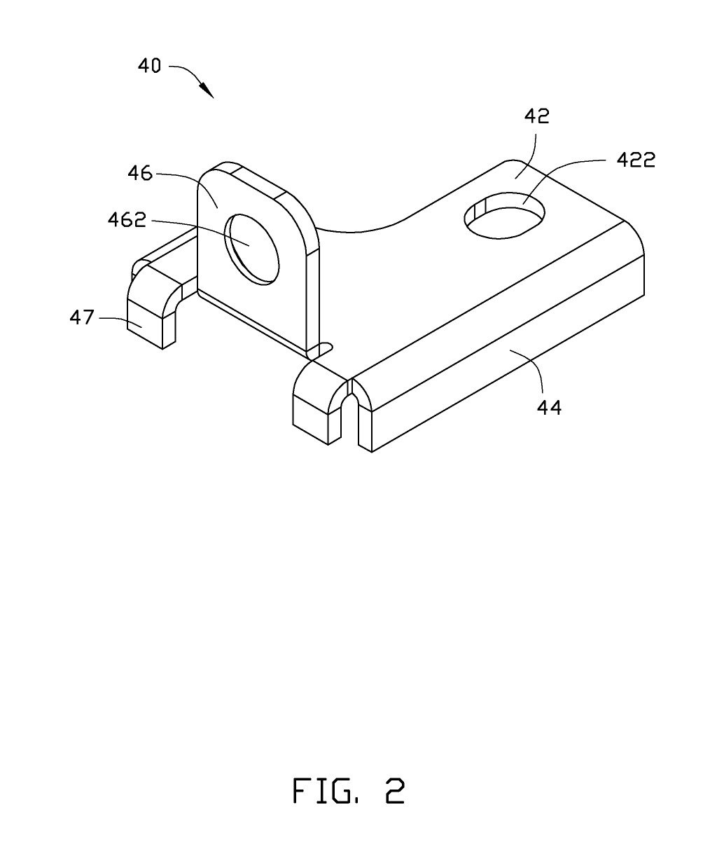

FIG. 2 shows the connecting member 40. The connecting member 40 includes a top plate 42, two side plates 44 extending down from two opposite sides of the top plate 42, a connecting plate 46 perpendicularly extending up from a middle of one end of the top plate 42, and two L-shaped hooks 47 extending down from the end of the top plate 42 at opposite sides of the connecting plate 46. The connecting plate 46 defines a through hole 462. An opposite end of the top plate 42 defines an installing hole 422.

In the embodiment, the fastener 60 is a screw.

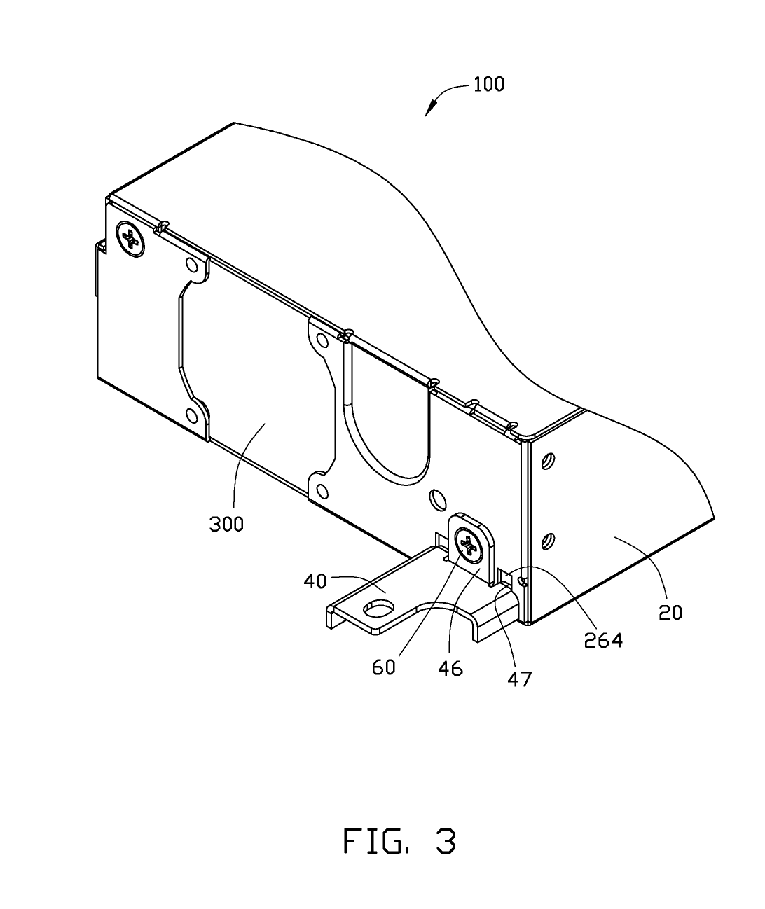

FIG. 3 shows that in assembly of the mounting structure 100. The hooks 47 of the connecting member 40 are inserted into the positioning holes 264 of the casing 20 from outside of the casing 20, with the connecting plate 46 abutting against an outer surface of the end wall 26. The through hole 462 is aligned with the mounting hole 262 of the casing 20. The fastener 60 extends through the though hole 462, to be latched to the mounting hole 262 of the casing 20. Thereby, the connecting member 40 is firmly mounted on the casing 20, to dampen vibrations of the power supply 300.

The mounting structure 100 is mounted to a rack (not show) by a screw extending through the installing hole 422.

If the fastener 60 loosens, the connecting member 40 will not detach from the casing 20 because of the hooks 47 latching in the positioning holes 264.

It is believed that the present embodiment and its advantages will be understood from the foregoing description, and it will be apparent that various changes may be made thereto without departing from the spirit and scope of the description or sacrificing all of their material advantages, the example hereinbefore described merely being exemplary embodiment.

What is claimed is:

1. A mounting structure, comprising:
a casing for receiving a power supply, the casing comprising an end wall defining a mounting hole and a positioning hole;
a connecting member comprising a connecting plate defining a through hole, and a hook; and
a fastener extending through the through hole of the connecting member to engage with the mounting hole of the casing;
wherein the hook of the connecting member is latched into the positioning hole of the casing.

2. The mounting structure of claim 1, wherein the positioning hole is below the mounting hole.

3. The mounting structure of claim 1, wherein the connecting member comprises a top plate, and two side plates extending down from two sides of the top plate, the connecting plate extends up from an end of the top plate, the hook extends down from the end of the top plate adjacent to the connecting plate.

4. The mounting structure of claim 1, wherein the hook is L-shaped.

5. The mounting structure of claim 1, wherein the fastener is a screw.
